(19) United States
(12) Patent Application Publication
(10) Pub. No.: US 2025/0273619 A1
(43) Pub. Date: Aug. 28, 2025

(54) METHOD OF HYBRID BONDING USING DIE DISTRIBUTION MODEL

(71) Applicant: Tokyo Electron Limited, Tokyo (JP)

(72) Inventors: Partha MUKHOPADHYAY, Oviedo, FL (US); H. Jim FULFORD, Marianna, FL (US); Zuriel CARIBE, Albany, NY (US); Mark I. GARDNER, Austin, TX (US)

(73) Assignee: Tokyo Electron Limited, Tokyo (JP)

(21) Appl. No.: 18/975,562

(22) Filed: Dec. 10, 2024

Related U.S. Application Data
(60) Provisional application No. 63/556,990, filed on Feb. 23, 2024.

(51) Int. Cl. H01L 23/00

(52) U.S. Cl. CPC H01L 24/80; H01L 24/05; H01L 2224/05578; H01L 2224/05647; H01L 2224/05686; H01L 2224/0569; H01L 2224/80031; H01L 2224/80047; H01L 2224/80895; H01L 2224/80896; H01L 2224/80948; H01L 2924/37001

(57) ABSTRACT

A method of hybrid bonding includes accessing first dies sourced from a first wafer, accessing second dies sourced from a second wafer and accessing third dies sourced from a third wafer. The first, second and third dies each include a respective bonding surface that includes a respective metal material recessed below a surface of a respective dielectric material. The first wafer has a larger diameter than the second and third wafers. An average metal recess depth of the second dies differs from an average metal recess depth of the third dies. A die pairing process is executed that matches the first dies with the second and third dies to form paired dies having combined metal recess depths within a range. An annealing process is executed to bond the paired dies such that corresponding dielectric surfaces bond with each other and corresponding metal materials expand to bond with each other.

### INCORPORATION BY REFERENCE

This present disclosure claims the benefit of U.S. Provisional Application No. 63/556,990, filed on Feb. 23, 2024, which is incorporated herein by reference in its entirety.

### FIELD OF THE INVENTION

This disclosure relates generally to semiconductor manufacturing and particularly to packaging and stacking of dies as a technique for transistor stacking or 3D formation of semiconductors.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, and yet scaling efforts are running into greater challenges as scaling enters single-digit nanometer semiconductor device fabrication nodes. Semiconductor device fabricators have expressed a desire to continue to improve “power performance, area, cost” or PPAC by implementing three-dimensional integration strategies or “3DI”. Many of these strategies employ stacking, such as die to die, die to wafer, and wafer to wafer for 3DI of circuits, transistors, memory cells, and interconnections between them.

### SUMMARY

The present disclosure relates to methods of hybrid bonding.

According to a first aspect of the disclosure, a method of hybrid bonding is provided. The method includes accessing first dies sourced from a first wafer, accessing second dies sourced from a second wafer, and accessing third dies sourced from a third wafer. The first dies each include a first bonding surface that includes a first dielectric material and a first metal material. A surface of the first metal material is recessed below a surface of the first dielectric material. The second dies each include a second bonding surface that includes a second dielectric material and a second metal material. A surface of the second metal material is recessed below a surface of the second dielectric material. The third dies each include a third bonding surface that includes a third dielectric material and a third metal material. A surface of the third metal material is recessed below a surface of the third dielectric material. The first wafer has a larger wafer diameter than the second wafer and the third wafer. The first wafer has a larger metal recess depth variation than the second wafer and the third wafer. An average metal recess depth of the second dies is different from an average metal recess depth of the third die. A die pairing process is executed that matches the first dies with the second dies and the third dies to form paired dies that have combined metal recess depths within a predetermined range. An annealing process is executed to bond the paired dies such that corresponding dielectric surfaces bond with each other and corresponding metal materials within corresponding combined metal recesses expand to bond with each other.

In some embodiments, a first chemical-mechanical polishing (CMP) process is executed on the first wafer to recess the surface of the first metal material below the surface of the first dielectric material. A second CMP process is executed on the second wafer to recess the surface of the second metal material below the surface of the second dielectric material. A third CMP process is executed on the third wafer to recess the surface of the third metal material below the surface of the third dielectric material.

In some embodiments, the second CMP process and the third CMP process are executed based on a metal recess depth variation of the first wafer.

In some embodiments, the second CMP process and the third CMP process are executed so that a difference between the average metal recess depth of the second dies and the average metal recess depth of the third dies corresponds to a difference between metal recess depths at two locations on the first wafer.

In some embodiments, before executing the first CMP process, a plurality of CMP processes are executed on a plurality of wafers to recess a surface of a respective metal material below a surface of a respective dielectric material, resulting in a gradient of average metal recess depths of respective dies from each of the plurality of wafers. The first wafer has a larger wafer diameter than the plurality of wafers. The plurality of wafers include the second wafer and the third wafer. The plurality of CMP processes include the second CMP process and the third CMP process.

In some embodiments, after executing the first CMP process, at least the second wafer and the third wafer are selected from the plurality of wafers based on a metal recess depth variation of the first wafer.

In some embodiments, the second CMP process and the third CMP process differ in at least one CMP parameter selected from the group consisting of polishing duration, polishing pressure, polishing temperature, relative velocity, slurry composition, slurry pH, abrasive particle size and an additive.

In some embodiments, the second CMP process has a shorter polishing duration than the third CMP process.

In some embodiments, the executing the die pairing process includes matching a first group of the first dies with the second dies and matching a second group of the first dies with the third dies. The average metal recess depth of the second dies is smaller than the average metal recess depth of the third dies. An average metal recess depth of the first group of the first dies is larger than an average metal recess depth of the second group of the first dies.

In some embodiments, the first group of the first dies are closer to a center of the first wafer than the second group of the first dies are.

In some embodiments, one of the second dies is picked from a dicing tape, and the one of the second dies is placed onto one of the first group of the first dies.

In some embodiments, the first wafer has a wafer diameter of 200 mm, 300 mm or 450 mm. The second wafer has a wafer diameter of 50 mm, 75 mm, 100 mm, 125 mm, 150 mm or 200 mm. The third wafer has a wafer diameter of 50 mm, 75 mm, 100 mm, 125 mm, 150 mm or 200 mm.

In some embodiments, the first dielectric material, the second dielectric material and the third dielectric material include a same dielectric material. The first metal material, the second metal material and the third metal material include a same metal material.

In some embodiments, the same dielectric material includes at least one selected from the group consisting of silicon oxide, silicon carbonitride, silicon nitride, silicon and a polymer. The same metal material includes copper.

In some embodiments, a first metal recess depth is identified for each of the first dies, resulting in first metal recess depths that vary by location on the first wafer. A second metal recess depth is identified for a subset of the second dies to estimate the average metal recess depth of the second dies. A third metal recess depth is identified for a subset of the third dies to estimate the average metal recess depth of the third dies.

In some embodiments, the paired dies include all of the first dies, and the annealing process is a single batch annealing process.

According to a second aspect of the disclosure, a method of hybrid bonding is provided. The method includes accessing first dies sourced from a first wafer. Each die from the first dies has a bonding surface that includes a first dielectric material and a first metal material. The first metal material has been recessed below a surface of the first dielectric material as a result of a first chemical-mechanical polishing (CMP) process. A depth profile value is identified for each die from the first dies, resulting in a first set of depth profile values that vary by location on the first wafer. Each depth profile value is based on measurement data. Each depth profile value represents a recess depth of metal relative to the surface of the dielectric layer for each die. A second set of depth profile values are calculated for pairing with dies from the first dies. The second set of depth profile values have two or more different depth profile values. Second dies sourced from two or more wafers are accessed. The two or more wafers have a smaller wafer diameter than a wafer diameter of the first wafer. Dies from the second dies include dies from a second wafer that includes a second dielectric material and a second metal material having been recessed below a surface of the second dielectric material to a second predetermined depth as a result of a second CMP process based on the second set of depth profile values. Dies from the second dies include dies from a third wafer that includes a third dielectric material and a third metal material having been recessed below a surface of the third dielectric material to a third predetermined depth as a result of a third CMP process based on the second set of depth profile values. The third predetermined depth differs from the second predetermined depth. A die pairing process is executed that matches dies from the first dies with dies from the second dies such that paired dies have an aggregate etch depth profile value within a predetermined range. An annealing process is executed to bond the paired dies such that opposing dielectric surfaces bond with each other and opposing metal materials within corresponding recesses expand and bond with each other.

In some embodiments, the third predetermined depth is larger than the second predetermined depth, and the third CMP process has a longer polishing duration than the second CMP process.

In some embodiments, the executing the die pairing process includes matching a first group of the first dies with dies from the second dies and matching a second group of the first dies with dies from the third dies. An average metal recess depth of the first group of the first dies is larger than an average metal recess depth of the second group of the first dies.

According to a third aspect of the disclosure, a method of hybrid bonding is provided. The method includes accessing first dies sourced from a first wafer. Each die from the first dies has a bonding surface that includes a dielectric material and a metal material. The metal material has been recessed below a surface of the dielectric material as a result of a first chemical-mechanical polishing (CMP) process. The first dies have variable metal recess depths based on position on the first wafer. Second dies sourced from two or more second wafers are accessed. The two or more second wafers have a smaller wafer diameter compared to the first wafer. Each die from the second dies has a bonding surface that includes the dielectric material and the metal material. The metal material has been recessed below a surface of the dielectric material as a result of a corresponding CMP process. The two or more second wafers have been subjected to variable CMP parameters resulting in the second dies having variable metal recess depths based on the variable CMP parameters. Dies from the first dies are paired with dies from the second dies such that combined metal recess depth is normalized among paired dies. An annealing process is executed that bonds the paired dies such that opposing dielectric surfaces bond with each other and opposing metal materials within corresponding recesses expand and bond with each other.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIGS. 1A, 1B and 1C show vertical cross-sectional views of a semiconductor device at various intermediate steps of manufacturing, in accordance with some embodiments of the present disclosure.

FIG. 2 shows a flow chart of a process for manufacturing a semiconductor device, in accordance with some embodiments of the present disclosure.

FIGS. 3A and 3B show top views of a semiconductor device at various intermediate steps of manufacturing in accordance with some embodiments of the present disclosure.

FIG. 4 shows a schematic view of die pairing in accordance with some embodiments of the present disclosure.

FIG. 5A shows a vertical cross-sectional view of paired dies in accordance with some embodiments of the present disclosure.

FIG. 5B shows a vertical cross-sectional view of paired dies in accordance with some embodiments of the present disclosure.

FIG. 5C shows a vertical cross-sectional view of paired dies in accordance with some embodiments of the present disclosure.

FIG. 6 shows a flow chart of a process for manufacturing a semiconductor device, in accordance with some embodiments of the present disclosure.

FIG. 7 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

Power, Performance, Area, and Cost (PPAC) improvements and Moore's Law's logarithmic performance increases in semiconductor devices have historically progressed primarily through aggressive doubling of transistor count every 18 months enabled by dimensional shrink without regard to functional chip type or the proper management of power scaling and heat dissipation. In the past two decades, as the industry has moved away from fully integrated large silicon area systems on chip (SoCs), it has become increasingly important for continual improvement in semiconductor devices to develop via optimizing PPAC at the system integration level through advanced packaging technologies. These technologies enable different functional chip types (such as “chiplets”) to be integrated into a single package and/or memory chips to be stacked vertically along with controller devices.

An important packaging technology for meeting the industry's ever-increasing needs is hybrid bonding. Hybrid bonding involves bonding a die to a die, or a die to a wafer, or a wafer to a wafer, in which both dielectric material and conductive material are exposed/uncovered and bonded to like materials on opposing substrates. Thus, opposing dielectric surfaces are bonded together, and then opposing metals are bonded together. The result is that there are dielectric-dielectric bonds as well as metal-metal bonds. This hybrid bonding technique is typically executed to bond wiring levels or structures together from two dies (or wafers). The bonding process involves annealing which results in expansion of the metal. For example, copper electrical connections and dielectric insulating materials on singulated dies or full wafers can be bonded face-to-face onto substrate dies or wafers, referred to as die-to-die (D2D), die-to-wafer (D2W) or wafer-to-wafer (W2W) hybrid bonding. After hybrid bonding, a substrate wafer can then be singulated to produce packaged modules.

A bonding surface can be prepared with conventional wiring techniques. This can include forming lines and/or vias in silicon oxide or other dielectric material, depositing metal using an overfill technique, and then using chemical-mechanical polishing (noted as CMP and also known as chemical-mechanical planarization) to remove the overburden. This planarization removes the overburden of metal, but also results in recessing metal below a top surface of the dielectric. Having a recess can be advantageous because metal bonding can be realized using an annealing process in which metal expands within its passage and then contacts corresponding metal in an opposing die until a physical connection and bond is established, thereby providing electric connections as well.

The challenge, however, is that CMP copper recess variations over the surface area of a wafer (such as a 200 mm or 300 mm wafer) are often inevitable. Such recess variations can lead to various post-oxide bonding copper recess gaps in hybrid bonding. As such, batch annealing under the same temperature and time results in dissimilarities in Cu-to-Cu hybrid bonding, either not enough expansion of metal to form a connection, or too much expansion entering dielectric bonding surface. This reduces yield. Moreover, the performance of the bonded dies in terms of electrical characteristics is also compromised.

This problem of mismatch of recess gaps can be further complicated when dies are sourced from wafers of different sizes. For example, some desired combinations of dies can include combining dies from a 300 mm wafer with dies from a 200 mm wafer, a 150 mm wafer, or smaller. As can be appreciated, other combinations may be desired due to design considerations, such as combining dies from a 200 mm wafer with dies from a 4-inch wafer.

Part of the challenge with pairing dies from different sized wafers is that the relatively larger wafers have more variability of recess depths compared to the smaller wafers. And with some of the smaller wafer sizes, the recess variability is not significant, with recess depths being largely uniform on the relatively smaller wafers. Thus, while the larger wafer produces dies with a range of recess depths, the smaller wafer has a generally uniform recess depth. This means that matching wafers to create a normalized gap is often not possible.

For die-to-die bonding, after bonding layers of dielectric and metal have been planarized, the wafer is diced or otherwise cut to generate separate, individual dies. With a conventional pick-and-place routine, a next-in-line die from a group of top dies is picked and placed on a next-in-line die from a group of bottom dies. The problem with this process is that metal recess depths of each die vary from die to die, depending on location on the wafer. This is because there can be center-to-edge dishing happening during the chemical-mechanical polishing process. For example, dies located on the outer edge of the wafer might have a 3 nm average recess depth, while dies located on the center of the wafer have a 7 nm average recess depth. This may be, for example, a 300 mm wafer. But when dies from a 300 mm wafer are to be paired with dies from a 150 mm wafer, there is an issue. This is because the comparatively smaller wafers have less variability from planarization. It may be the case that the 150 mm wafer, after CMP execution, results in all dies having approximately 6 nm of recess depth. This means that paired dies will have large variability in gaps between metal. In this example, it could be 3 nm with 6 nm for a 9 nm gap, or 6 nm with 6 nm for a 12 nm gap, or 9 nm with 6 nm for a 15 nm gap.

Accordingly, techniques herein include CMP biasing based on a desired range of recess depth variability. In other words, while the variability of recess depths in the larger wafer is unintentional, the variability from a set of smaller wafers is intentionally created to have a set of dies having variable recess depths for pairing to create normalized combined gaps.

Techniques herein provide methods of matching dies to be bonded for optimized or improved bonding of batches of dies. The term “pick-and-place” in semiconductor bonding, refers to the robotic process of grasping one die and positioning that die on another die for bonding, while aligning points to be connected. Because this bonding forms a combined circuit, ensuring that the electrical connections are aligned and properly formed is crucial for a working combined circuit. Accordingly, techniques herein match dies to make the combined recess depths as uniform as possible, with dies from comparatively smaller diameter wafers subjected to variable CMP processing to produce a variety of recess depths among available dies for picking and placing.

Techniques herein then execute multiple different CMP processes on the smaller wafers, or rather, CMP processes with different parameters such as polishing time. For this specific example, there may be three 150 mm wafers, the first is planarized to result in a 3 nm recess depth, while the second is planarized to result in a 6 nm recess depth, and then the third wafer is planarized to result in a 9 nm recess depth. Because the smaller wafer has fewer dies per wafer compared to the larger wafer, multiple smaller wafers might be needed for even pairing. And then after biasing the CMP conditions, a set of variable recess depth dies are generated from the set of smaller wafers. Now, with a set of variable recess depth dies from the larger wafer, and a set of variable recess depth dies from the smaller wafers, a distribution model can be used to match/pair dies to create a set of matched dies for bonding that have combined metal gaps that are as uniform as possible based on available dies. With combined gaps/recess depths uniform within an acceptable range, a batch bonding operation (e.g. annealing all samples under the same temperature and time irrespective of Cu recess depth variations on bottom dies) can be executed for high-yield bonding.

As discussed earlier, CMP Cu recess variations over the full 200/300 mm wafer are inevitable. Maintaining the same Cu recess gap at post-oxide-bonding condition after accounting for the CMP recess variations over the full wafer would allow batch annealing at the same temperature and thus yield goes up. Techniques herein, which can be embodied in software, can optimize the number of the bottom die productions to minimize the standard deviations. Wastage can be reduced by guiding the bottom dies in the proper channel. The same Cu recess gap can be maintained at post-oxide-bonding condition after accounting for the CMP recess variations over the full wafer. As a result, the gap would be the same which allows for baking/annealing of the bonded wafers in a batch under the same condition. The distribution model herein can be combined with a hybrid bonding tool to minimize that particular Cu recess gap variations by picking dies from various positions of the wafer to place on the corresponding positions of the dies.

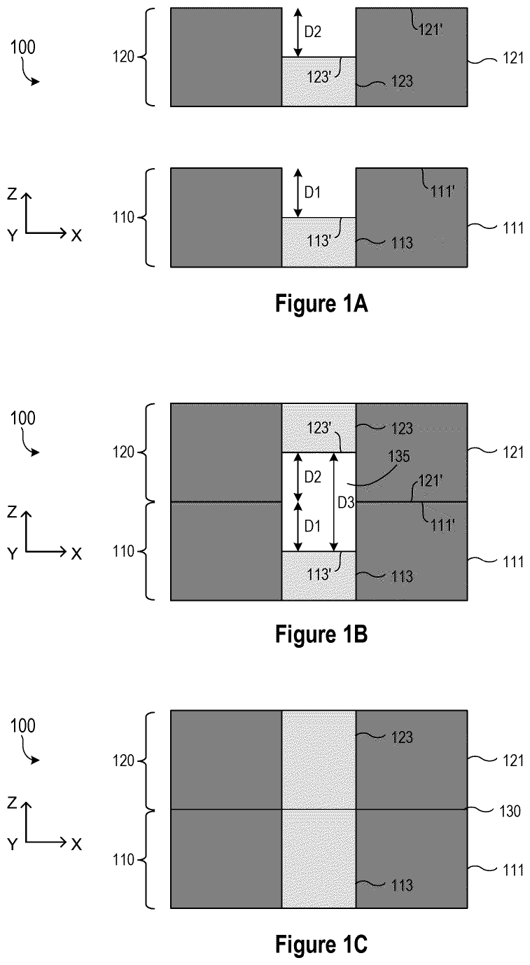

FIGS. 1A, 1B and 1C show vertical cross-sectional views of a semiconductor device 100 at various intermediate steps of manufacturing, in accordance with some embodiments of the present disclosure.

In FIG. 1A, the semiconductor device 100 can include a first die 110 and a second die 120. The first die 110 includes a first dielectric material 111 and a first metal material 113. A surface 113′ of the first metal material 113 is recessed below a surface 111′ of the first dielectric material 111 by a first recess depth D1. The second die 120 includes a second dielectric material 121 and a second metal material 123. A surface 123′ of the second metal material 123 is recessed below a surface 121′ of the second dielectric material 121 by a second recess depth D2.

The first dielectric material 111 can include, but is not limited to, silicon oxide, silicon carbonitride, silicon nitride, silicon, a polymer (e.g. polyimide) or any combinations thereof. Preferably, the first dielectric material 111 includes silicon oxide. The first metal material 113 can include, but is not limited to, copper, aluminum, gold, chromium, tantalum, titanium, ruthenium, tungsten or any combinations thereof. Preferably, the first metal material 113 includes copper, aluminum, gold or any combinations thereof. Preferably, the first metal material 113 includes copper.

The second dielectric material 121 can include, but is not limited to, silicon oxide, silicon carbonitride, silicon nitride, silicon, a polymer (e.g. polyimide) or any combinations thereof. Preferably, the second dielectric material 121 includes silicon oxide. The second metal material 123 can include, but is not limited to, copper, aluminum, gold, chromium, tantalum, titanium, ruthenium, tungsten or any combinations thereof. Preferably, the second metal material 123 includes copper, aluminum, gold or any combinations thereof. Preferably, the second metal material 123 includes copper.

In some embodiments, the first dielectric material 111 and the second dielectric material 121 can include a same dielectric material. The first metal material 113 and the second metal material 123 can include a same metal material. Preferably, the first dielectric material 111 and the second dielectric material 121 are both silicon oxide while the first metal material 113 and the second metal material 123 are both copper. Alternatively, the first dielectric material 111 and the second dielectric material 121 may include different dielectric materials. The first metal material 113 and the second metal material 123 may include different metal materials.

Note that FIG. 1A only shows part of the semiconductor device 100 for simplicity purposes. For example, bonding surfaces are shown while circuitry is omitted. The first die 110 can include a plurality of recess metals similar to the second metal material 123. While 110 and 120 are referred to as two dies, 110 and/or 120 can be wafers without departing from the spirits of the present disclosure. Additionally, the surface 113′ of the first metal material 113 and the surface 123′ of the second metal material 123 may not be entirely flat, but have another shape such as a dishing shape.

In FIG. 1B, the first die 110 can be used as a bottom die while the second die 120 can be used as a top die. That is, the second die 120 is flipped upside down and placed on top of the first die 110 so that the first die 110 and the second die 120 are oriented face to face. For example, a face side (e.g. circuitry) of the first die 110 and a face side (e.g. circuitry) of the second die 120 face towards each other while a back side (e.g. bulk semiconductor material) of the first die 110 and a back side (e.g. bulk semiconductor material) of the second die 120 face away from each other.

Particularly, the surface 111′ of the first dielectric material 111 and the surface 121′ of the second dielectric material 121 can be aligned and placed in contact with each other. The surface 113′ of the first metal material 113 and the surface 123′ of the second metal material 123 are spaced apart from each other by a recess gap 135 having a gap dimension of D3. As D3=D1+D2, D3 is also referred to as a combined metal recess depth D3.

In FIG. 1C, a hybrid bonding process is executed so that a bonding interface 130 is formed between the first die 110 and the second die 120. Specifically, the first dielectric material 111 and the second dielectric material 121 can be bonded to each other e.g. by a dielectric-dielectric bond. Then an annealing process can be executed so that the first metal material 113 and the second metal material 123 thermally expand to close the recess gap 135 and are bonded to each other e.g. by a metal-metal bond.

In a non-limiting example, a plasma activation process can be performed on the first die 110 and the second die 120, and deionized water (DIW) may be used to rinse the first die 110 and the second die 120. Then the first die 110 and the second die 120 can be aligned and pre-bonded. Pre-bonded dies may be inspected, for example using infrared light transmission imaging, and can be stripped and cleaned. The pre-bonded dies can further be bonded for instance by an annealing process. It should be understood that the first die 110 and the second die 120 may alternatively be bonded by other processes or techniques such as direct bonding, surface-activated bonding, plasma-activated bonding, anodic bonding, eutectic bonding, glass frit bonding, adhesive bonding, reactive bonding, transient liquid phase diffusion bonding, and/or the like.

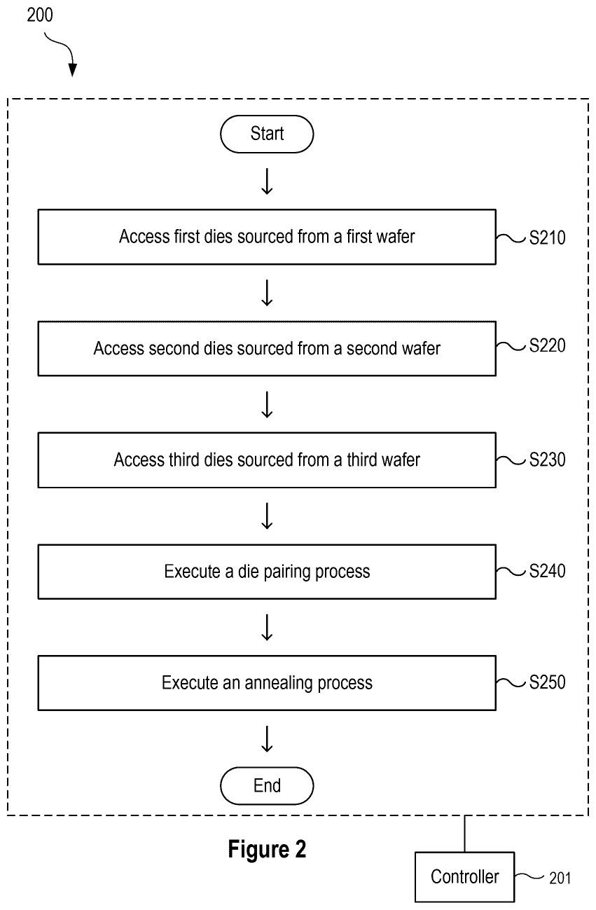

FIG. 2 shows a flow chart of a process 200 for manufacturing a semiconductor device, in accordance with some embodiments of the present disclosure. At step S210, first dies which are sourced from a first wafer are accessed. The first dies each include a first bonding surface that includes a first dielectric material and a first metal material. A surface of the first metal material is recessed below a surface of the first dielectric material. At step S220, second dies which are sourced from a second wafer are accessed. The second dies each include a second bonding surface that includes a second dielectric material and a second metal material. A surface of the second metal material is recessed below a surface of the second dielectric material. At step S230, third dies which are sourced from a third wafer are accesses. The third dies each include a third bonding surface that includes a third dielectric material and a third metal material. A surface of the third metal material is recessed below a surface of the third dielectric material. The first wafer has a larger wafer diameter than the second wafer and the third wafer. The first wafer has a larger metal recess depth variation than the second wafer and the third wafer. An average metal recess depth of the second dies is different from an average metal recess depth of the third dies. At step S240, a die pairing process is executed that matches the first dies with the second dies and the third dies to form paired dies that have combined metal recess depths within a predetermined range. At step S250, an annealing process is executed to bond the paired dies such that corresponding dielectric surfaces bond with each other and corresponding metal materials within corresponding combined metal recesses expand to bond with each other.

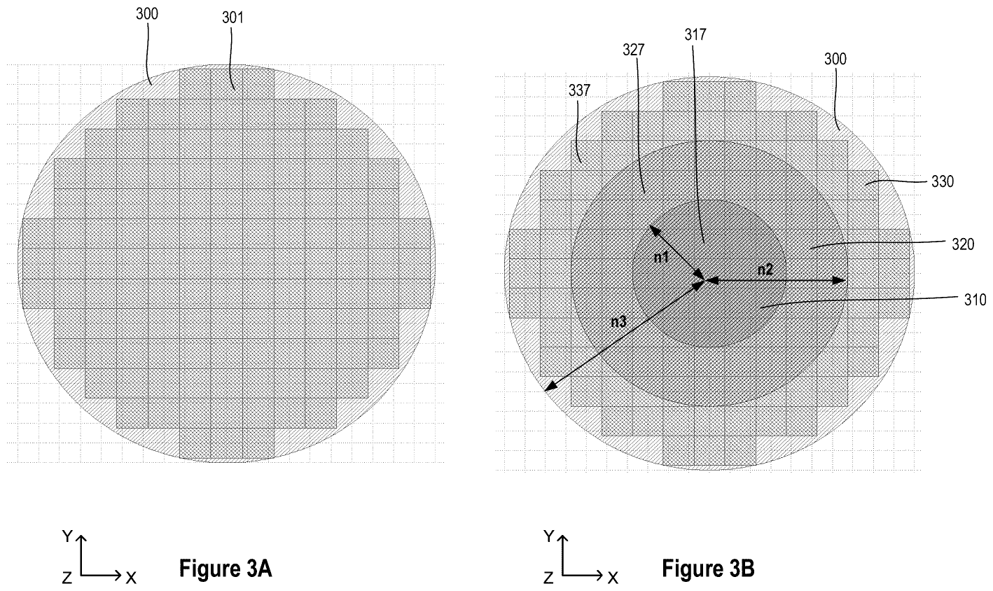

FIGS. 3A and 3B show top views of a semiconductor device at various intermediate steps of manufacturing in accordance with some embodiments of the present disclosure.

As illustrated in FIG. 3A, a first wafer 300 includes first dies 301. In this example, the first wafer 300 has a wafer diameter of 200 mm while the first dies 301 have a square shape with lateral dimensions of 15 mm×15 mm. FIG. 3A shows a maximum number of the first dies 301 (e.g. bottom dies) distributed on a 200 mm wafer with scribe lines. The maximum or total number of the first dies 301 that can fit inside the first wafer 300 is one hundred and twenty-one.

In FIG. 3B, a chemical-mechanical polishing (noted as CMP and also known as chemical-mechanical planarization) process is executed on the first wafer 300. With the CMP technique, Cu recess variations over a 200 mm wafer or larger are inevitable. It can approximately be divided into several zones based on the available data and standard deviations of recess depths. In this particular example, three zones have been taken: a center portion 317, a middle ring 327 and an outer ring 337.

The center portion 317 has a radius of n1 and an area of A1. A₁=πn₁². m1 is the number of dies in the center portion 317. m1 number of dies has a recess depth of d1. The middle ring 327 has a radius of n2 and an area of A2. A₂=πn₂²−A₁. m2 is the number of dies in the middle ring 327. m2 number of dies has a recess depth of d2. The outer ring 337 has a radius of n3 and an area of A3. A₃=πn₃²−A₂−A₁. m3 is the number of dies in the outer ring 337. m3 number of dies has a recess depth of d3. Due to CMP recess variations, d1≠d2≠d3. When n1<n2<n3, therefore, m1<m2≤m3.

In a non-limiting example, n1=37 mm; n2=68 mm; and n3=100 mm. Therefore, A1=43 cm²; A2=102 cm²; and A3=169 cm². The first dies 301 have a square shape with lateral dimensions of 15 mm×15 mm. Accordingly, m1=13+3=16; m2=41+6=47; and m3=52+6=58. m1+m2+m3=16+47+58=121.

In some embodiments, for bonding die, after simulations are executed to determine the exact numbers of top dies with specific recess depth profiles for bottom dies (e.g. 310, 320 and 330)), a distribution model can estimate/instruct the various Cu recess depths needed from the corresponding incoming wafers based on their diameter, material properties, applications, values, significance, and CMP techniques. For the bonding top dies, usually, the III-V wafers have a wafer diameter of 100 mm to 150 mm. Possibly the III-V wafers possess a single zone for Cu recess depth. Excessive bottom dies can be distributed to future batches to reduce wastage greatly. As can be appreciated, first dies can be sourced from multiple larger wafers while second (and optionally third, fourth, etc.) dies can be sourced from multiple smaller wafers. For matches that cannot be made within tolerance, such dies can be kept for subsequent selection after more dies are generated. Alternatively, if there are significant pairs of dies that can have a normalized gap that is outside a predetermined range, then those pairs of dies can be annealed using a different annealing process, such as with different time and/or temperature based on the combined gap.

Note that a specific die may sit across a boundary between two zones and designated to either of the two zones, depending on the specific recess depth of the specific die. In this example, three zones have been taken. In other examples, any number of zones (e.g. two, four, five, six or more zones) can be taken, depending on the CMP Cu recess variation across the first wafer 300. The CMP Cu recess variation and recess depths can be measured by atomic force microscopy or other measurement techniques. In this example, the center portion 317 is circular while the middle ring 327 and the outer ring 337 are ring-shaped. In other examples, zones may have various shapes such as an elliptical shape, an irregular shape, etc. depending on the CMP Cu recess variation across the first wafer 300. Additionally, a different number of the first dies 301 can be arranged in a different pattern on the first wafer 300.

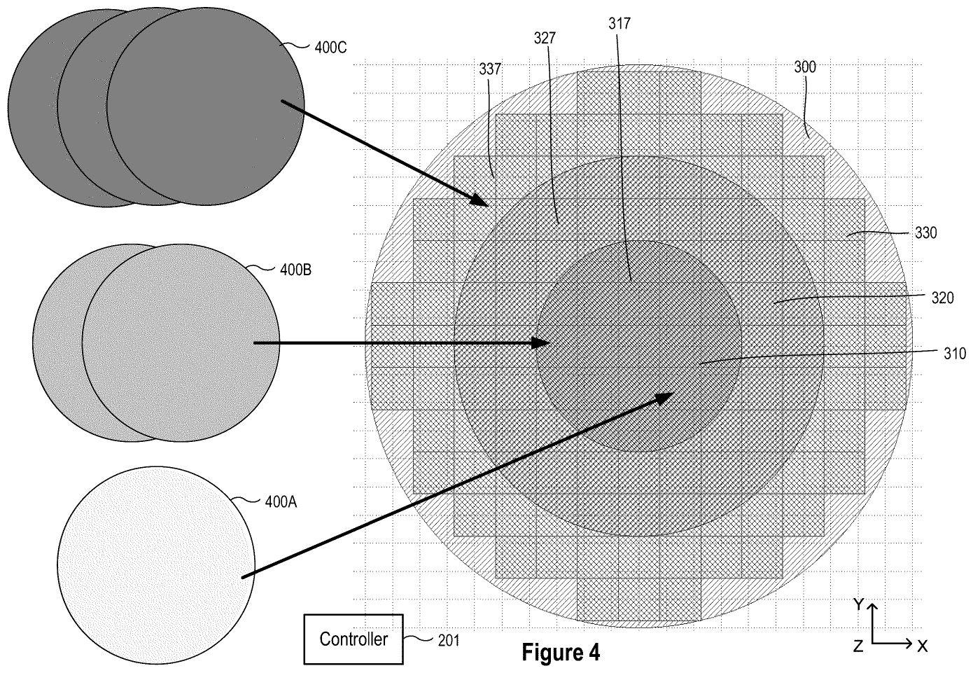

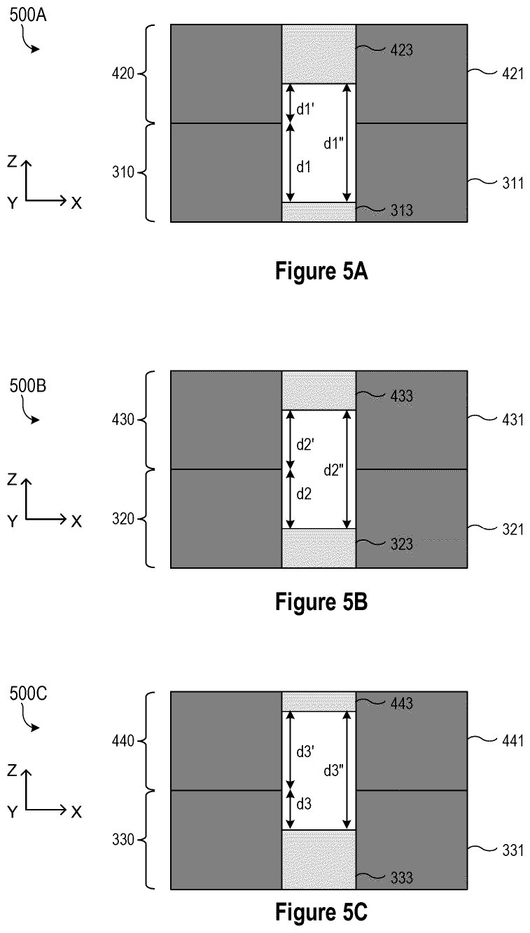

FIG. 4 shows a schematic view of die pairing, and FIGS. 5A, 5B and 5C show vertical cross-sectional views of paired dies, in accordance with some embodiments of the present disclosure.

As shown, the first wafer 300 includes a first group of dies 310 having a recess depth of d1 in the center portion 317, a second group of dies 320 having a recess depth of d2 in the middle ring 327 and a third group of dies 330 having a recess depth of d3 in the outer ring 337. Second dies 420 having a recess depth of d1′ can be sourced from at least one second wafer 400A. Third dies 430 having a recess depth of d2′ can be sourced from at least one third wafer 400B. Fourth dies 440 having a recess depth of d3′ can be sourced from at least one fourth wafer 400C.

As a result, paired dies 500A can be formed between the first group of dies 310 and the second dies 420 to have a combined recess depth of d1″=d1′+d1. Paired dies 500B can be formed between the second group of dies 320 and the third dies 430 to have a combined recess depth of d2″=d2′+d2. Paired dies 500A can be formed between the third group of dies 330 and the fourth dies 440 to have a combined recess depth of d3″=d3′+d3.

As mentioned earlier, d1+d2 d3 due to CMP recess variation. For instance, d1>d2>d3. Accordingly, d1′<d2′<d3′ may be needed so that d1″, d2″ and d3″ are close to one another, or identical to one another, or in a predetermined range. For instance, |d1″−d2″|≤delta, |d2″−d3″|≤delta and |d1″−d3″|≤delta, where delta can be 0 nm to 5 nm e.g. 0 nm, 0.5 nm, 1 nm, 1.5 nm, 2 nm, 3 nm, 4 nm, 5 nm or any values therebetween. Preferably, delta is 0 nm to 1 nm. Preferably, delta is 0 nm, in which case d1″=d2″=d3″. Here, delta represents a maximum difference in combined recess depths across the paired dies. When delta is controlled in the predetermined range, the paired dies 500A, 500B and 500C can be batch-annealed or annealed together without the need for separate annealing processes at different temperatures and/or other annealing conditions. Note that delta depends on specific design needs and is not particularly limited to the aforementioned range(s).

In some embodiments, d1=9 nm; d2=6 nm; and d3=3 nm. Accordingly, d1′ can be 3 nm; d2 can be 6 nm; and d3 can be 9 nm. In another embodiment, d1′=2 nm; d2′=5 nm; and d3′=8.5 nm. In yet another embodiment, d1′=5 nm; d2′=7.5 nm; and d3′=11 nm. In yet another embodiment, d1′=3.1 nm; d2′=6.3 nm; and d3′=8.8 nm.

The first wafer 300 can have a larger wafer diameter than the at least one second wafer 400A, the at least one third wafer 400B and the at least one fourth wafer 400C. As mentioned earlier, a relatively larger wafer has more variability of recess depths compared to a smaller wafer. Here, the first wafer 300 can include different zones with variable recess depths such as d1, d2 and d3. The at least one second wafer 400A, the at least one third wafer 400B and the at least one fourth wafer 400C can respectively be approximated to have a recess depth of d1′, d2′ and d3′. Note that d1, d2, d3, d1′, d2′ and d3′ can represent an average value of recess depths. For example, the first group of dies 310 in the center portion 317 of the first wafer 300 may have an average recess depth of d1 while the first group of dies 310 may each have a respective recess depth deviating insignificantly from d1 or within a predetermined range around d1. Similarly, it should be understood that the at least one third wafer 400B may not have a completely uniform recess depth across the entire wafer. However, the third dies 430 sourced from the at least one third wafer 400B can each have a respective recess depth deviating insignificantly from d2′ or within a predetermined range around d2′.

In some embodiments, a first metal recess depth for each of the first dies (e.g. 310, 320 and 330) can be identified, resulting in first metal recess depths (d1, d2 and d3) that vary by location on the first wafer 300. Due to the smaller recess depth variation because of a smaller wafer diameter, a second metal recess depth for a subset (e.g. one, two, three, four, five or more) of the second dies 420 on the at least one second wafer 400A may be identified to estimate the average metal recess depth (e.g. d1′) of the second dies 420. Similarly, a third metal recess depth may be identified for a subset (e.g. one, two, three, four, five or more) of the third dies 430 on the at least one third wafer 400B to estimate the average metal recess depth (e.g. d2′) of the third dies 430. A fourth metal recess depth may be identified for a subset (e.g. one, two, three, four, five or more) of the fourth dies 440 on the at least one fourth wafer 400C to estimate the average metal recess depth (e.g. d3′) of the fourth dies 440.

In some embodiments, the first wafer 300 can have a wafer diameter of 200 mm, 300 mm or 450 mm. The at least one second wafer 400A can have a wafer diameter of 50 mm, 75 mm, 100 mm, 125 mm, 150 mm or 200 mm. The at least one third wafer 400B can have a wafer diameter of 50 mm, 75 mm, 100 mm, 125 mm, 150 mm or 200 mm. The at least one fourth wafer 400C can have a wafer diameter of 50 mm, 75 mm, 100 mm, 125 mm, 150 mm or 200 mm.

In one embodiment, the first wafer 300 has a wafer diameter of 200 mm. Accordingly, the at least one second wafer 400A, the at least one third wafer 400B and the at least one fourth wafer 400C can each independently have a wafer diameter of 50 mm, 75 mm, 100 mm, 125 mm or 150 mm, preferably 100 mm, 125 mm or 150 mm. For example, the at least one second wafer 400A, the at least one third wafer 400B and the at least one fourth wafer 400C can all have a wafer diameter of 150 mm.

In another embodiment, the first wafer 300 has a wafer diameter of 300 mm. Accordingly, the at least one second wafer 400A, the at least one third wafer 400B and the at least one fourth wafer 400C can each independently have a wafer diameter of 50 mm, 75 mm, 100 mm, 125 mm, 150 mm or 200 mm, preferably 100 nm, 125 mm, 150 mm or 200 mm. For example, the at least one second wafer 400A, the at least one third wafer 400B and the at least one fourth wafer 400C can all have a wafer diameter of 200 mm.

Note that dimensions of various wafer diameters are mentioned herein merely for illustrative purposes and are not limiting. As a skilled artisan would understand, wafer diameters can also be expressed in inches, and a value expressed in millimeters and a value expressed in inches for a same wafer are not always equal to each other. For instance, 50 mm, 75 mm, 100 mm, 125 mm, 150 mm, 200 mm, 300 mm and 450 mm may respectively be known as 2 inches, 3 inches, 4 inches, 5 inches, 6 inches, 8 inches, 12 inches and 18 inches. However, 300 mm=11.811 inches, not exactly 12 inches. 200 mm=7.874 inches, not exactly 8 inches. Therefore, a value of a wafer diameter in the present disclosure generally represents a range of the value*(100%±10%), preferably the value*(100%±5%), preferably the value*(100%±3%), preferably the value. For instance, a wafer diameter of 200 mm represents a range of 180 mm to 220 mm, preferably 190 mm to 210 mm, preferably 194 mm to 206 mm, preferably 200 mm.

Additionally, the first group of dies 310 can each include a dielectric material 311 and a metal material 313. The second group of dies 320 can each include a dielectric material 321 and a metal material 323. The third group of dies 330 can each include a dielectric material 331 and a metal material 333. The second dies 420 can each include a dielectric material 421 and a metal material 423. The third dies 430 can each include a dielectric material 431 and a metal material 433. The fourth dies 440 can each include a dielectric material 441 and a metal material 443.

The dielectric materials 311, 321 and/or 331 can each independently correspond to the first dielectric material 111. The metal materials 313, 323 and/or 333 can each independently correspond to the first metal material 113. The dielectric materials 421, 431 and/or 441 can each independently correspond to the second dielectric material 121. The metal materials 423, 433 and/or 443 can each independently correspond to the second metal material 123. Descriptions have been provided earlier and will be omitted herein for simplicity purposes. In a non-limiting example, the dielectric materials 311, 321, 331, 421, 431 and 441 include a same dielectric material such as silicon oxide while the metal materials 313, 323, 333, 423, 433 and 443 include a same metal material such as copper.

As discussed earlier, a die pairing process can be executed to obtain the paired dies 500A, 500B and 500C so that d1 “, d2” and d3″ are close to one another, or identical to one another, or in a predetermined range. As a result, the paired dies 500A, 500B and 500C can all be annealed together in one batch without the need for separate annealing processes at different temperatures and/or other annealing conditions. In other words, the aforementioned one hundred and twenty-one bottom first dies 301 (or 310, 320 and 330) of the first wafer 300 can be paired with dies from the second dies 420, the third dies 430 and the fourth dies 440 and then annealed together in a single annealing process.

In some embodiments, a first CMP process is executed on the first wafer 300 to recess a surface of a metal material (e.g. 313, 323 and 333) below a surface of a first dielectric material (e.g. 311, 321 and 331). A second CMP process is executed on the at least one second wafer 400A to recess the surface of the metal material 423 below the surface of the dielectric material 421. A third CMP process is executed on the at least one third wafer 400B to recess the surface of the metal material 433 below the surface of the dielectric material 431. A fourth CMP process is executed on the at least one fourth wafer 400C to recess the surface of the metal material 443 below the surface of the dielectric material 441.

The first, second, third and fourth CMP processes can be executed in any order without limitations. In some embodiments, the first CMP process is executed. Then, a metal recess depth variation of the first wafer 300A is determined, and d1, d2 and d3 are obtained. Subsequently, the second, third and fourth CMP processes are executed based on the metal recess depth variation of the first wafer 300A and/or based on d1, d2 and d3. Particularly, the second, third and fourth CMP processes are executed so that d1″, d2″ and d3″ are close to one another, or identical to one another, or in a predetermined range as previously discussed. For example, a difference between the average metal recess depth (e.g. d1′) of the second dies 420 and the average metal recess depth (e.g. d2′) of the third dies 430 can correspond to a difference between metal recess depths at two locations (e.g. 317 and 327) on the first wafer 300.

In some embodiments, the second, third and fourth CMP processes are executed before the first CMP process. More generally speaking, before executing the first CMP process, a plurality of CMP processes can be executed on a plurality of wafers to recess a surface of a respective metal material below a surface of a respective dielectric material, resulting in a series of average metal recess depths of respective dies from each of the plurality of wafers. The plurality of wafers each have a smaller wafer diameter than the first wafer 300. The plurality of CMP processes can include the second, third and fourth CMP processes. For instance, the series of average metal recess depths may range from 1 nm to 20 nm e.g. 1 nm, 2 nm, 3 nm, 4 nm, 5 nm . . . 16 nm, 17 nm, 18 nm, 19 nm, 20 nm or any values therebetween. As a result, a library of dies are obtained which have a range or gradient of metal recess depths. Then, the first CMP process is executed on the first wafer 300, and a metal recess depth variation of the first wafer 300 can be determined to obtain d1, d2 and d3. Subsequently, dies can be selected from the library of dies to pair with dies from the first wafer 300 based on the metal recess depth variation of the first wafer 300 and/or based on d1, d2 and d3 so that d1 “, d2” and d3″ are close to one another, or identical to one another, or in a predetermined range as previously discussed.

Moreover, the second, third and fourth CMP processes may differ from each other in at least one CMP parameter selected from the group consisting of polishing duration, polishing pressure, polishing temperature, relative velocity, slurry composition, slurry pH, abrasive particle size and an additive. Such difference in the at least one CMP parameter can lead to difference in average metal recess depth. Preferably, the second, third and fourth CMP processes differ from each other in the polishing duration while other CMP parameters are kept the same or substantially the same. For instance, the second CMP process can have a shorter polishing duration than the third CMP process so that d1′<d2′, and the third CMP process can have a shorter polishing duration than the fourth CMP process so that d2′<d3′. Similarly, the library of dies having a gradient of metal recess depths can be obtained by CMP processes that have a gradient of polishing durations (while other CMP parameters are kept the same or substantially the same).

Additionally, a controller 201 can optionally be used to implement the process 200 in FIG. 2 and/or the hybrid bonding process shown in FIGS. 3A, 3B and 4. Components of a CMP tool, a hybrid bonding tool, etc. can be connected to and controlled by the controller 201 that may optionally be connected to a corresponding memory storage unit and user interface (all not shown). Various wafer/die operations (e.g. CMP and hybrid bonding) can be executed via the user interface, and various processing recipes and operations can be stored in the memory storage unit.

It will be recognized that the controller 201 may be coupled to various components of the CMP tool, the hybrid bonding tool, etc. to receive inputs from and provide outputs to the components. For example, the controller 201 can be configured to receive monitoring data from a corresponding tool. The controller 201 can also be configured to adjust knobs and control settings for the corresponding tool. Of course the adjustments can be manually made as well.

It will also be recognized that the controller 201 may be coupled to various components of the process 200 to receive inputs from and provide outputs to the components. For example, the controller 201 can be configured to implement steps S210, S220, S230, S240 and/or S250. The controller 201 can be configured to implement the aforementioned distribution model and receive d1, d2 and d3 to determine d1′, d2′ and d3′. Of course, one or more functions of the controller 201 can also be manually accomplished.

The controller 201 can be implemented in a wide variety of manners. In one example, the controller 201 is a computer. In another example, the controller 201 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

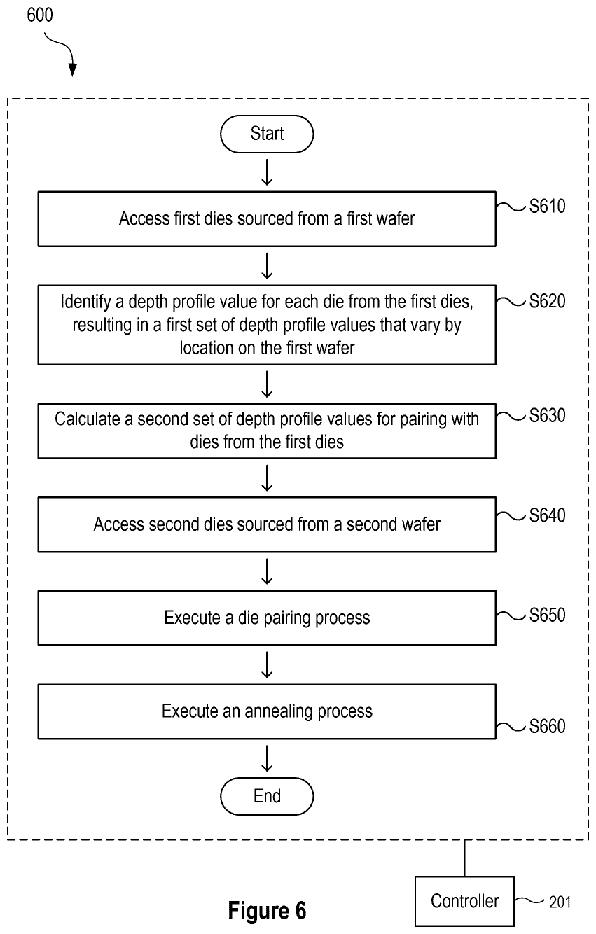

FIG. 6 shows a flow chart of a process for manufacturing a semiconductor device, in accordance with some embodiments of the present disclosure. At step S610, first dies sourced from a first wafer are accessed. Each die from the first dies has a bonding surface that includes a first dielectric material and a first metal material. The first metal material has been recessed below a surface of the first dielectric material as a result of a first chemical-mechanical polishing (CMP) process. At step S620, a depth profile value for each die from the first dies is identified, resulting in a first set of depth profile values that vary by location on the first wafer. Each depth profile value is based on measurement data. Each depth profile value represents a recess depth of metal relative to the surface of the dielectric layer for each die. At step S630, a second set of depth profile values are calculated for pairing with dies from the first dies. The second set of depth profile values have two or more different depth profile values. At step S640, second dies sourced from two or more wafers are accessed. The two or more second wafers have a smaller wafer diameter than a wafer diameter of the first wafer. Dies from the second dies include dies from a second wafer that includes a second dielectric material and a second metal material having been recessed below a surface of the second dielectric material to a second predetermined depth as a result of a second CMP process based on the second set of depth profile values. Dies from the second dies include dies from a third wafer that includes a third dielectric material and a third metal material having been recessed below a surface of the third dielectric material to a third predetermined depth as a result of a third CMP process based on the second set of depth profile values. The third predetermined depth differs from the second predetermined depth. At step S650, a die pairing process is executed that matches dies from the first dies with dies from the second dies such that paired dies have an aggregate etch depth profile value within a predetermined range. At step S660, an annealing process is executed to bond the paired dies such that opposing dielectric surfaces bond with each other and opposing metal materials within corresponding recesses expand and bond with each other. Additionally, the controller 201 can be used to implement the process 600 in FIG. 6. Similar descriptions have been provided above and will be omitted herein for simplicity purposes.

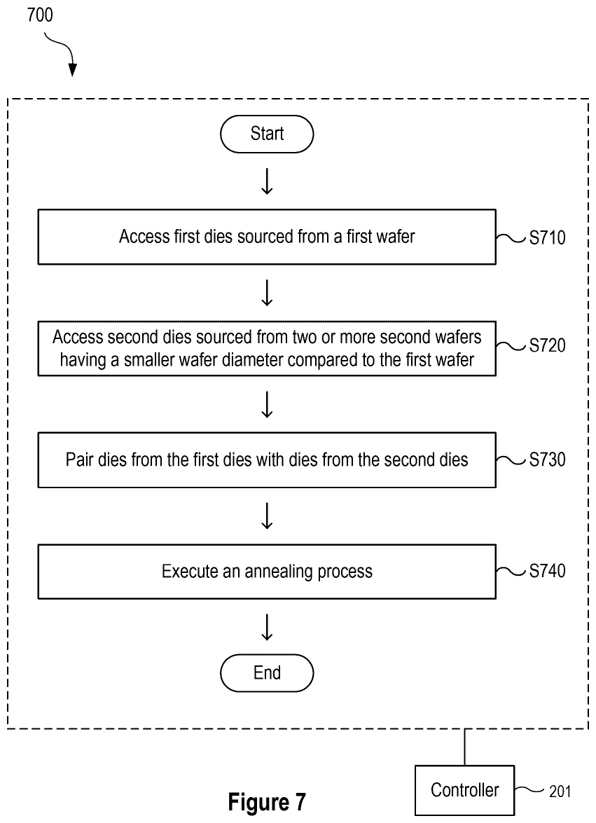

FIG. 7 shows a flow chart of a process for manufacturing a semiconductor device, in accordance with some embodiments of the present disclosure. At step S710, first dies sourced from a first wafer are accessed. Each die from the first dies has a bonding surface that includes a dielectric material and a metal material. The metal material has been recessed below a surface of the dielectric material as a result of a first chemical-mechanical polishing (CMP) process. The first dies have variable metal recess depths based on position on the first wafer. At step S720, second dies sourced from two or more second wafers are accessed. The two or more second wafers have a smaller wafer diameter compared to the first wafer. Each die from the second dies has a bonding surface that includes the dielectric material and the metal material. The metal material has been recessed below a surface of the dielectric material as a result of a corresponding CMP process. The two or more second wafers have been subjected to variable CMP parameters resulting in the second dies having variable metal recess depths based on the variable CMP parameters. At step S730, dies from the first dies are paired with dies from the second dies such that combined metal recess depth is normalized among paired dies. At step S740, an annealing process is executed that bonds the paired dies such that opposing dielectric surfaces bond with each other and opposing metal materials within corresponding recesses expand and bond with each other. Additionally, the controller 201 can be used to implement the process 700 in FIG. 7. Similar descriptions have been provided above and will be omitted herein for simplicity purposes.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of hybrid bonding, the method comprising:
accessing first dies sourced from a first wafer, the first dies each comprising a first bonding surface that includes a first dielectric material and a first metal material, a surface of the first metal material recessed below a surface of the first dielectric material;
accessing second dies sourced from a second wafer, the second dies each comprising a second bonding surface that includes a second dielectric material and a second metal material, a surface of the second metal material recessed below a surface of the second dielectric material;
accessing third dies sourced from a third wafer, the third dies each comprising a third bonding surface that includes a third dielectric material and a third metal material, a surface of the third metal material recessed below a surface of the third dielectric material, wherein the first wafer has a larger wafer diameter than the second wafer and the third wafer, the first wafer has a larger metal recess depth variation than the second wafer and the third wafer, and an average metal recess depth of the second dies is different from an average metal recess depth of the third dies;
executing a die pairing process that matches the first dies with the second dies and the third dies to form paired dies that have combined metal recess depths within a predetermined range; and
executing an annealing process to bond the paired dies such that corresponding dielectric surfaces bond with each other and corresponding metal materials within corresponding combined metal recesses expand to bond with each other.

2. The method of claim 1, further comprising:
executing a first chemical-mechanical polishing (CMP) process on the first wafer to recess the surface of the first metal material below the surface of the first dielectric material;
executing a second CMP process on the second wafer to recess the surface of the second metal material below the surface of the second dielectric material; and
executing a third CMP process on the third wafer to recess the surface of the third metal material below the surface of the third dielectric material.

3. The method of claim 2, wherein:
the second CMP process and the third CMP process are executed based on a metal recess depth variation of the first wafer.

4. The method of claim 3, wherein:
the second CMP process and the third CMP process are executed so that a difference between the average metal recess depth of the second dies and the average metal recess depth of the third dies corresponds to a difference between metal recess depths at two locations on the first wafer.

5. The method of claim 2, further comprising:
before executing the first CMP process, executing a plurality of CMP processes on a plurality of wafers to recess a surface of a respective metal material below a surface of a respective dielectric material, resulting in a gradient of average metal recess depths of respective dies from each of the plurality of wafers,
wherein the first wafer has a larger wafer diameter than the plurality of wafers, the plurality of wafers include the second wafer and the third wafer, and the plurality of CMP processes include the second CMP process and the third CMP process.

6. The method of claim 5, further comprising:
after executing the first CMP process, selecting at least the second wafer and the third wafer from the plurality of wafers based on a metal recess depth variation of the first wafer.

7. The method of claim 2, wherein:
the second CMP process and the third CMP process differ in at least one CMP parameter selected from the group consisting of polishing duration, polishing pressure, polishing temperature, relative velocity, slurry composition, slurry pH, abrasive particle size and an additive.

8. The method of claim 7, wherein:
the second CMP process has a shorter polishing duration than the third CMP process.

9. The method of claim 1, wherein:
the executing the die pairing process comprises matching a first group of the first dies with the second dies and matching a second group of the first dies with the third dies,
the average metal recess depth of the second dies is smaller than the average metal recess depth of the third dies, and
an average metal recess depth of the first group of the first dies is larger than an average metal recess depth of the second group of the first dies.

10. The method of claim 9, wherein:
the first group of the first dies are closer to a center of the first wafer than the second group of the first dies are.

11. The method of claim 9, further comprising:
picking one of the second dies from a dicing tape; and
placing the one of the second dies onto one of the first group of the first dies.

12. The method of claim 1, wherein:
the first wafer has a wafer diameter of 200 mm, 300 mm or 450 mm,
the second wafer has a wafer diameter of 50 mm, 75 mm, 100 mm, 125 mm, 150 mm or 200 mm, and
the third wafer has a wafer diameter of 50 mm, 75 mm, 100 mm, 125 mm, 150 mm or 200 mm.

13. The method of claim 1, wherein:
the first dielectric material, the second dielectric material and the third dielectric material include a same dielectric material, and
the first metal material, the second metal material and the third metal material include a same metal material.

14. The method of claim 13, wherein:
the same dielectric material includes at least one selected from the group consisting of silicon oxide, silicon carbonitride, silicon nitride, silicon and a polymer, and
the same metal material includes copper.

15. The method of claim 1, further comprising:
identifying a first metal recess depth for each of the first dies, resulting in first metal recess depths that vary by location on the first wafer;
identifying a second metal recess depth for a subset of the second dies to estimate the average metal recess depth of the second dies; and
identifying a third metal recess depth for a subset of the third dies to estimate the average metal recess depth of the third dies.

16. The method of claim 1, wherein:
the paired dies include all of the first dies, and
the annealing process is a single batch annealing process.

17. A method of hybrid bonding, the method comprising:
accessing first dies sourced from a first wafer, each die from the first dies having a bonding surface that includes a first dielectric material and a first metal material, the first metal material having been recessed below a surface of the first dielectric material as a result of a first chemical-mechanical polishing (CMP) process;
identifying a depth profile value for each die from the first dies, resulting in a first set of depth profile values that vary by location on the first wafer, each depth profile value based on measurement data, each depth profile value representing a recess depth of metal relative to the surface of a dielectric layer for each die;
calculating a second set of depth profile values for pairing with dies from the first dies, the second set of depth profile values having two or more different depth profile values;
accessing second dies sourced from two or more wafers that have a smaller wafer diameter than a wafer diameter of the first wafer, wherein dies from the second dies include dies from a second wafer that includes a second dielectric material and a second metal material having been recessed below a surface of the second dielectric material to a second predetermined depth as a result of a second CMP process based on the second set of depth profile values, wherein dies from the second dies include dies from a third wafer that includes a third dielectric material and a third metal material having been recessed below a surface of the third dielectric material to a third predetermined depth as a result of a third CMP process based on the second set of depth profile values, wherein the third predetermined depth differs from the second predetermined depth;
executing a die pairing process that matches dies from the first dies with dies from the second dies such that paired dies have an aggregate etch depth profile value within a predetermined range; and
executing an annealing process to bond the paired dies such that opposing dielectric surfaces bond with each other and opposing metal materials within corresponding recesses expand and bond with each other.

18. The method of claim 17, wherein:
the third predetermined depth is larger than the second predetermined depth, and
the third CMP process has a longer polishing duration than the second CMP process.

19. The method of claim 18, wherein:
the executing the die pairing process comprises matching a first group of the first dies with dies from the second dies and matching a second group of the first dies with dies from the third dies, and
an average metal recess depth of the first group of the first dies is larger than an average metal recess depth of the second group of the first dies.

20. A method of hybrid bonding, the method comprising:
accessing first dies sourced from a first wafer, each die from the first dies having a bonding surface that includes a dielectric material and a metal material, the metal material having been recessed below a surface of the dielectric material as a result of a first chemical-mechanical polishing (CMP) process, the first dies having variable metal recess depths based on position on the first wafer;
accessing second dies sourced from two or more second wafers having a smaller wafer diameter compared to the first wafer, each die from the second dies having a bonding surface that includes the dielectric material and the metal material, the metal material having been recessed below a surface of the dielectric material as a result of a corresponding CMP process, wherein the two or more second wafers have been subjected to variable CMP parameters resulting in the second dies having variable metal recess depths based on the variable CMP parameters;
pairing dies from the first dies with dies from the second dies such that combined metal recess depth is normalized among paired dies; and
executing an annealing process that bonds the paired dies such that opposing dielectric surfaces bond with each other and opposing metal materials within corresponding recesses expand and bond with each other.
